(19) United States
(12) Patent Application Publication
(10) Pub. No.: US 2004/0001355 A1
(43) Pub. Date: Jan. 1, 2004

(54) Low-cost, serially-connected, multi-level mask-programmable read-only memory

(75) Inventor: Mark G. Johnson, Los Altos, CA (US)

Correspondence Address: ZAGORIN O'BRIEN & GRAHAM, L.L.P., 7600B N. CAPITAL OF TEXAS HWY., SUITE 350, AUSTIN, TX, 78731, US

(73) Assignee: Matrix Semiconductor, Inc.

(21) Appl. No.: 10/185,208

(22) Filed: Jun. 27, 2002

(51) Int. Cl. G11C 19/08; G11C 16/04

(52) U.S. Cl. 365/185.03; 365/185.05

(57) ABSTRACT

An integrated circuit includes a serially-connected, multi-level, mask-programmed read-only memory array. The memory cells are preferably programmed using selective ion implantation of at least two threshold-adjusting ion implants during the manufacture of the integrated circuit to store more than one bit of information within each memory cell, which are chosen to generate an evenly spaced set of different transistor threshold voltages.

### BACKGROUND

1. Field of the Invention

This invention relates to integrated circuit memory devices, and more particularly to mask-programmable read-only memory devices.

2. Description of the Related Art

Semiconductor Read Only Memory (ROM) may be used in electronic systems when designers want the absolutely lowest possible cost per bit. As used herein, “ROM” is synonymous with “mask ROM” or “mask-programmable ROM”, i.e. semiconductor memory whose contents are programmed in the factory, and whose contents may be read but not subsequently altered. The ROM factory is generally a semiconductor manufacturing line, and the programming is usually accomplished via photolithographic steps or “masks” and may therefore be termed mask-programmable.

Mask programmed ROMs, such as that described by Rogers (in U.S. Pat. No. 4,059,826) are well known in the art. In U.S. Pat. No. 4,142,176, Dozier describes serially-connected MOSFET memory cells used in a mask-programmed ROM, and Kawagoe and Tsuji also describe them in “Minimum Size ROM Structure Compatible with Silicon-Gate E/D MOS LSI,” IEEE Journal of Solid State Circuits, vol. SC-11, No. 3, June 1976, pp. 360-364. In U.S. Pat. No. 5,197,027, Challa describes serially-connected MOSFET memory cells used in an electrically-erasable programmable ROM (i.e., EEPROM). A serially-connected merged-transistor memory cell structure is described by Y. Kitano et al, in “A 4-Mbit Full-Wafer ROM,” IEEE Journal of Solid State Circuits, Vol. SC-15, No. 4, August 1980, pp. 686-693.

Conventional memory cells can store two different states, and are thus referred to as “binary” or two-level cells. Other memory cells capable of storing >2 states are frequently referred to in the art as “multi-level” memory cells. Multi-level memory cells are described in the art, including by Bayliss et al, in “The Interface Processor for the Intel VLSI 432 32-bit Computer,” IEEE Journal of Solid State Circuits, vol. SC-16, No. 5, October 1981, pp. 522-530. U.S. Pat. No. 6,326,269 to Jeng and Lee also describes multi-level read-only memory cells.

However, even with the advances to date, ROM customers (system designers) desire even more ROMs at yet-lower cost per bit. There is a very large and presently untapped market for ROMs having cost per bit lower than today's offerings.

### SUMMARY

The present invention provides mask ROM at dramatically lower cost per bit than today's conventional ROMs by utilizing a serially-connected, multi-level storage FET memory cell.

This invention reduces cost because it uses a serially-connected memory cell. Such a cell decreases the die area occupied by each cell, hence more cells pack into a given area and the cost per bit is reduced. This invention further reduces cost by using a multi-level storage cell capable of more than two (2) stored states per memory cell. This allows more than one bit of information to be stored into a single memory cell, thereby packing a larger number of bits per unit area.

In a preferred embodiment, each memory cell is programmed using a number “N” (at least two) of masking steps to selectively ion implant the cell, and preferably provides 2^{N} different states in the memory cell to store N bits per cell. Preferably, N=3 or N=4, and the programmed threshold voltages are evenly spaced. Such a memory in accordance with the present invention may result in a slower memory access speed than traditional ROMs using N=1, but for many applications a lower cost is more desirable than high speed. To further reduce costs, the memory array may be implemented using no more than two layers of interconnect metallization, and even more preferably all but one layer of metallization may be eliminated.

### BRIEF DESCRIPTION OF THE DRAWINGS

The present invention may be better understood, and its numerous objects, features, and advantages made apparent to those skilled in the art by referencing the accompanying drawings.

FIG. 1 is a schematic diagram of a portion of a memory array in accordance with an exemplary embodiment of the present invention.

FIG. 2 is a layout diagram of the portion of a memory array depicted in FIG. 1 in accordance with an exemplary embodiment of the present invention.

FIG. 3 is a schematic diagram of a portion of a memory array and support circuits in accordance with another exemplary embodiment of the present invention.

The use of the same reference symbols in different drawings indicates similar or identical items.

### DESCRIPTION OF THE PREFERRED EMBODIMENT(S)

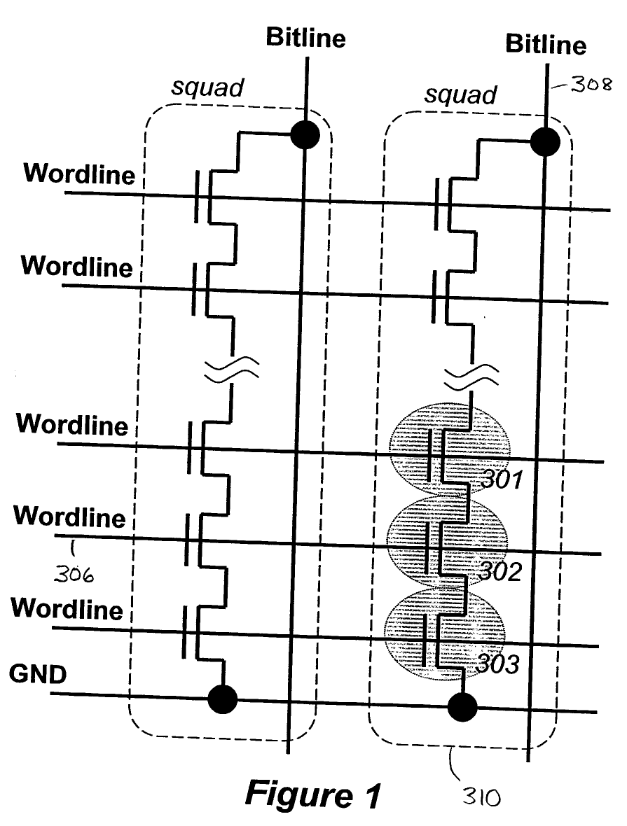

FIG. 1 shows a schematic diagram of several memory cells in accordance with a preferred embodiment of this invention. Each memory cell is formed by an MOS transistor with mask-selectable threshold adjustment implants. The gate electrode of each memory cell transistor is connected to a word line. The drain and source terminals of each memory cell transistor are respectively connected to the memory cell transistor above, and below, the memory cell. For example, memory cell 302 includes a transistor whose gate terminal is connected to a word line 306, whose drain terminal is connected to the transistor source terminal of memory cell 301, and whose source terminal is connected to the transistor drain terminal of memory cell 303.

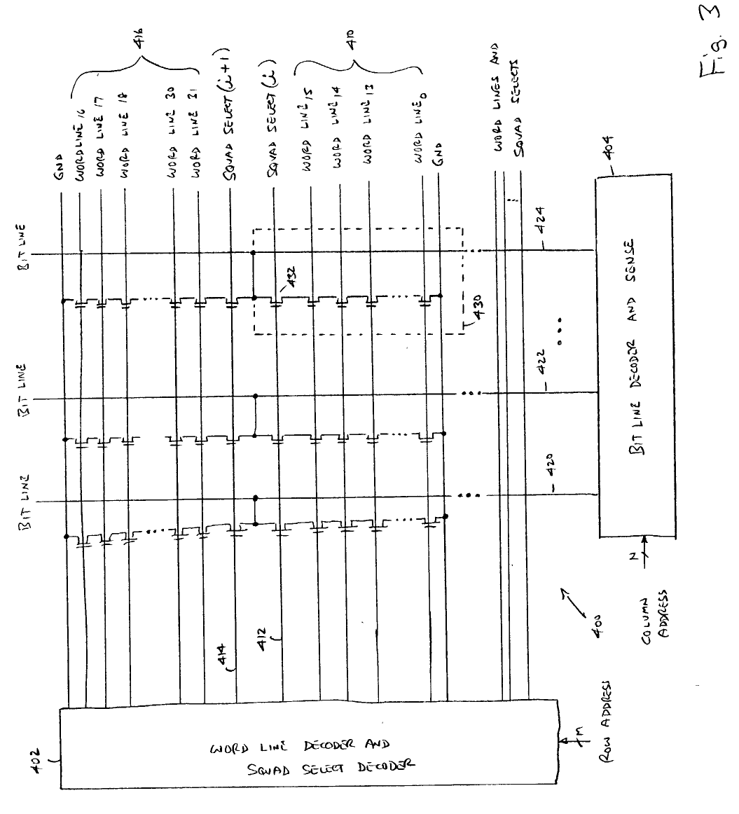

A number “S” of memory cells are connected in series (i.e., in a “NAND” stack arrangement) between a bit line and ground. Preferably the number “S” is an integral power of two to facilitate address decoding, although other numbers of memory cells are also contemplated. These series connected cells may be referred to as a “squad”, and “S” is the number of cells in a squad. In other embodiments each squad may include additional elements, such as one or more selection devices (e.g. switching transistors) as shown in FIG. 3. A selection device may be connected between the serially-connected memory cells of the squad and its associated bit line (i.e., at the “top” of the squad), or alternatively connected between the serially-connected memory cells of the squad and the ground line (i.e., at the “bottom” of the squad), or both. Such a selection device may be utilized to select one squad and deselect other squads connected to the same bit line, while a particular memory cell within the squad is selected by a word line decoder.

As shown in FIG. 3, a memory array 400 is shown which includes a selection device at the “top” or bit line end of each squad. Such a configuration is preferred over a selection device at the “bottom” end of each squad to reduce capacitive loading on the selected bit line arising from non-selected squads, although both arrangements are contemplated. Memory squad 430 includes a group of serially-connected memory cells, here represented as 16 such memory cells, each respectively coupled to an associated one of a group of word lines 410. The squad 430 further includes a selection device 432 which, when selected by an appropriate level such as VDD on a squad select (i) signal 412, couples the squad 430 to its associated bit line 424. Other squad select signals, such as squad select (i+1) signal 414, typically remain low to isolate the selected bit line from the non-selected squads associated with the bit line. The bit lines 420, 422, and 424 are shown coupled to a bit line decoder and sense circuit block 404, while the word lines 410 and 416 and squad select signals 412 and 414 are coupled to and driven by a word line decoder and squad select decoder 402.

Preferably the states stored in each memory cell are programmed by transistor threshold voltage-adjusting ion implants. A number “N” of masking steps may be used to control “N” different ion implantation steps, which may be selected to provide (2^{N}) different states in each memory cell and store N bits per cell. As long as N>1 different masks and ion implant steps are used, the number of stored states per cell which may be achieved will exceed 2.

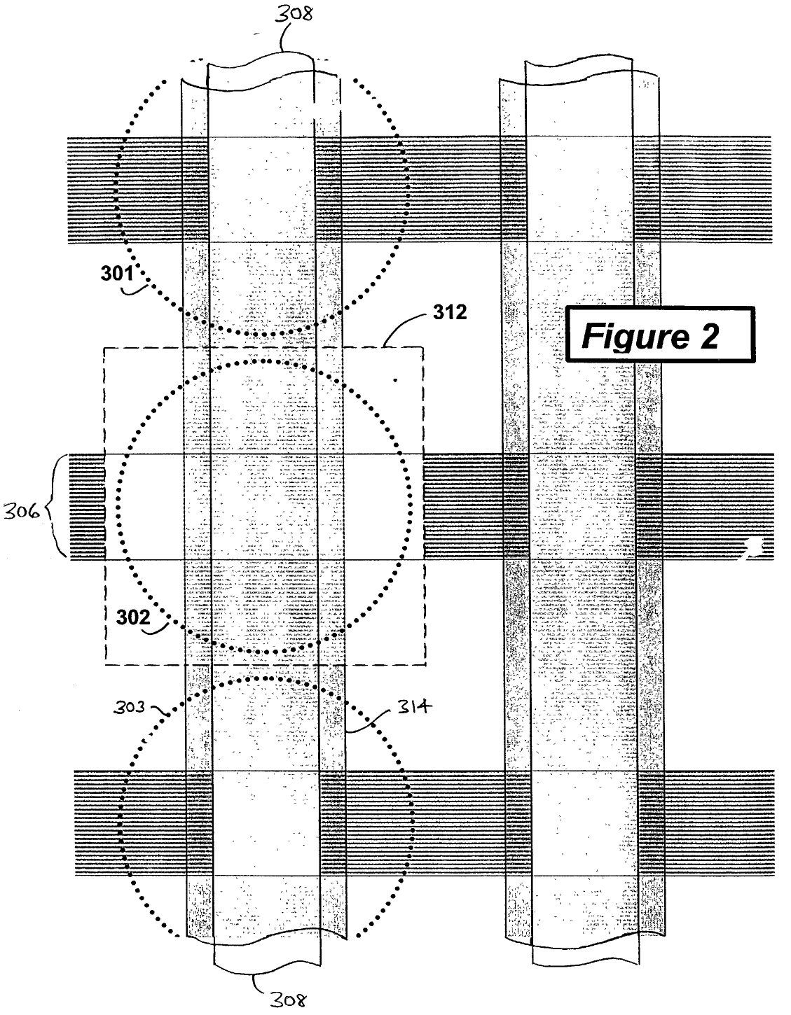

FIG. 2 shows an exemplary layout of several memory cells. Preferably each memory cell is a single MOS transistor which is defined by the intersection of a vertical source/drain stripe 314, a horizontal gate stripe, and zero or more channel implant mask features (some programmed states require zero implant mask features, others require N implant mask features). Memory cell 302 is in the middle of squad 310, and is serially-connected with cell 301 above and cell 303 below by way of the vertical source/drain stripe 314. The word line 306 forms the gate of the MOS transistor in memory cell 302. The squad 310 is associated with bit line 308 which is preferably routed overhead in a metallization layer, such as a single metal interconnect layer. A mask feature 312 (here shown as a square) is present (or absent) on each of the “N” ion implant masks that program the memory cell. If mask feature 312 is present on an ion implant mask, that implant is blocked (prevented) from adjusting the threshold of memory cell 302 (assuming, of course, a certain overall polarity through the manufacturing process). On the other hand, if mask feature 312 is absent on an ion implant mask, that implant is allowed to adjust the threshold of memory cell 302. Other shapes are possible for the mask feature 312, as long as a given ion implant may be either allowed to penetrate into the channel region of the memory cell transistor 302 (and thus shift its threshold voltage, V_{T}), or alternatively is prevented from entering the channel region thus leaves unaffected the threshold voltage.

Suppose that a particular embodiment of this invention uses N=3 ion implant masks. Each of the 3 masks might, or might not, have mask feature 312 present. Thus there are 2³=8 possible combinations of implants for memory cell 302, as set forth in the following Table 1:

TABLE 1

| Rect. 312 | Rect. 312 | Rect. 312 | |
|---|---|---|---|
| present on | present on | present on | |
| implant | implant | implant | Implants received |
| mask #3? | mask #2? | mask #1 | by cell 302 |
| N | N | N | (none) |
| N | N | Y | 1 |
| N | Y | N | 2 |
| N | Y | Y | 1, 2 |
| Y | N | N | 3 |
| Y | N | Y | 1, 3 |
| Y | Y | N | 2, 3 |
| Y | Y | Y | 1, 2, 3 |

By careful choice of implant conditions, each of these eight combinations of implants can produce a different threshold voltage for the MOS transistor within cell 302. The eight threshold voltages represent eight stored states in the cell, which encodes three bits of information. More generally, if “N” implant masks are used, each cell therefore stores 2^{N} states, which may be used to encode N bits of information. Alternatively, memory cells which store a number of states “M” which is not an integral power of two may still be used to store more than one bit of information per memory cell. For example, two memory cells, each capable of storing three different states, may be used together to provide three bits of data for every two memory cells, thus storing more than one bit per cell.

Information is stored in this exemplary memory cell as one of 2^{N} possible threshold voltages of the MOS transistor within cell 302. Recovering the stored information (i.e. reading the cell) requires the ROM to detect which of the 2^{N} possible threshold voltages has been programmed. Many different methods may be employed to perform this detection, although the invention is not to be limited to any particular method or means for reading the memory cells as described below.

In one exemplary scheme to read a memory cell, an address is presented which uniquely refers to a single memory cell in the array. Such a cell may be referred to as the “selected cell” and the squad in which the selected cell is physically located is called the “selected squad.” All word lines in the selected squad are initially driven HIGH, for example, to the positive power supply voltage VDD or to some other suitable bias voltage. All other word lines (not associated with the selected squad) are initially driven LOW, for example, to the negative power supply voltage VSS. This ensures that all MOS transistors in the selected squad are turned ON irrespective of the particular threshold voltage of each cell, and ensures that all other transistors that might affect the selected squad's bit line are turned OFF (assuming that the memory cells utilize enhancement mode N-channel transistors).

Next, the selected word line (e.g., word line 306) is slowly ramped from high to low. When the word line voltage is above the programmed threshold voltage of the MOS transistor in cell 302, current can flow from the bit line, through the squad 310 (including through the selected cell 302) and to ground. But when the selected word line voltage is below the programmed threshold voltage of the MOS transistor in cell 302, current cannot flow from the bit line, through the squad, and to ground. Thus, sensing circuitry can be coupled to the selected bit line 308 to detect whether current is or is not flowing, which tells whether cell 302's transistor is ON or OFF. When the gradually falling selected word line voltage eventually turns memory cell 302's transistor OFF, that word line voltage is approximately equal to the memory cell transistor threshold voltage. Measuring the word line voltage at this switching event provides a measurement of the transistor's threshold voltage. The stored state may then be obtained by table lookup, for example, in a table similar to Table 1 above.

Many alternative techniques may be used to read cell 302's transistor threshold voltage, and thus determine the programmed data stored therein. The voltages for HIGH and LOW can be chosen to be something other than the power supply voltages. The selected word line voltage could ramp up rather than down. Moreover, instead of ramping, the word line voltage could move in several discrete steps (e.g. 2^{N}−1 steps), either up or down, and engineers skilled in the art can devise many other variations.

Other embodiments are contemplated in which the memory cell transistors (and/or squad select transistors) may be N-channel devices whose threshold voltage may be a negative value (i.e., depletion-mode operation), at least for some of the programmed states, if not for all such programmed states. In such an embodiment having negative threshold voltages, the selected word line may be driven to a negative voltage by using a boosted-below-ground word line driver circuit, such as may be implemented using P-channel (PMOS) transistors. Alternatively, a negative power supply voltage may be received by the integrated circuit to facilitate driving a selected word line to a negative voltage. In such embodiments, the selected word line may be ramped (or stair-stepped) in either direction, as described above, to determine at which word line voltage the current through the memory cell turns on or off. Similarly, other embodiments are contemplated using P-channel transistors, whether the programmed states are enhancement-mode, depletion mode, or a mixture thereof. Consequently, a memory array in accordance with the present invention may be implemented using any of a wide variety of different readout schemes.

Each respective implant step adjusts the threshold voltage of the MOS transistor within each memory cell that is exposed to the implant by a respective ΔV volts. Otherwise, if the respective implant is blocked (e.g., by a mask feature such as blocking mask feature 312) or otherwise prevented from reaching the memory cell (e.g., “direct writing” of the implant without using an actual mask) the threshold voltage remains substantially unchanged, i.e. the change is zero volts.

If implant #1 is allowed to reach the memory cell MOS transistor, the threshold voltage changes by ΔV₁ volts, where the subscript 1 refers to implant #1. If implant #1 is prevented from reaching the memory cell MOS transistor, the threshold voltage is virtually unchanged. Similarly, if implant #2 reaches the memory cell MOS transistor, the threshold voltage changes by an additional ΔV₂ volts, and if implant #2 is prevented from reaching the memory cell MOS transistor, the threshold voltage is left virtually unchanged (i.e., changes by zero volts). This continues for implant #3, #4, . . . , through implant #N for a memory cell which is capable of storing N bits of information.

The effects of several successive implants upon the MOS transistor threshold voltage are additive, so for example if a cell receives implants #1 and #3 but does not receive implant #2, its threshold voltage is changed by a total (ΔV₁+0+ΔV₃) volts. We can rewrite the Table 1 above, now recording the changes in memory cell MOS transistor threshold voltage, to that shown below in Table 2:

TABLE 2

| Implant #3? | Implant #2? | Implant #1? | Threshold change |
|---|---|---|---|
| N | N | N | 0 |
| N | N | Y | ΔV₁ |
| N | Y | N | ΔV₂ |
| N | Y | Y | ΔV₂ + ΔV₁ |
| Y | N | N | ΔV₃ |
| Y | N | Y | ΔV₃ + ΔV₁ |
| Y | Y | N | ΔV₃ + ΔV₂ |
| Y | Y | Y | ΔV₃ + ΔV₂ + ΔV₁ |

An important consideration emerges from this table. Consider the second, third, and fifth rows of the table. They correspond to a threshold change of ΔV₁, ΔV₂, and ΔV₃, respectively. We can see that it is important to have (ΔV₁≠ΔV₂), and (ΔV₂≠ΔV₃), and (ΔV₁≠ΔV₃). Otherwise the states in the second, third, and fifth states would be indistinguishable and would consequently reduce the number of distinguishable states that each memory cell could store (and thus reduce the number of bits of information that could otherwise be stored in the memory cell).

For ease of read circuit (i.e., bit line sense circuitry) implementation, it is preferable to have the threshold voltage changes be uniform from state to state. In other words, it is preferred that each state have a threshold change that is a constant “x” volts greater than the preceding state, as set forth in Table 3:

TABLE 3

| Implant | Implant | Implant | Threshold | Threshold |
|---|---|---|---|---|
| #3? | #3? | #3? | change | change |
| N | N | N | 0 | 0 |
| N | N | Y | ΔV₁ | x |
| N | Y | N | ΔV₂ | 2x |
| N | Y | Y | ΔV₂ + ΔVphd 1 | 3x |
| Y | N | N | ΔV₃ | 4x |
| Y | N | Y | ΔV₃ + ΔV₁ | 5x |
| Y | Y | N | ΔV₃ + ΔV₂ | 6x |
| Y | Y | Y | ΔV₃ + ΔV₂ + ΔV₁ | 7x |

Again inspecting the second, third, and fifth rows of the table, we see that preferred embodiments of this invention select ion implant conditions such that the change in threshold voltage corresponding to each implant follows a binary progression: (ΔV₁=x), (ΔV₂=2x), (ΔV₃=4x), and so forth. This gives a uniform change in threshold voltage from each state to the subsequent state, which is preferred for simplicity of implementation. It should be appreciated that the individual ion implantations may be performed in any order, irrespective of whether the group of implants forms a binary progression. For example, in the above example, implant #2 may be performed first, followed by implant #3, then lastly by implant #1. The resulting transistor threshold voltage shifts nonetheless follow a binary progression and the resulting threshold voltages are substantially uniformly spaced.

In a preferred embodiment suitable for use with a power supply voltage V_{DD}=1.5 volts, exemplary nominal values for the respective change in threshold voltage corresponding to each respective implant are ΔV₁=125 mV, ΔV₂=250 mV, and ΔV₃=500 mV. As used herein, the threshold voltage of a transistor refers to the nominal value of the threshold voltage, as some variation inevitably occurs, as with many semiconductor parameters. As used herein, a plurality of threshold voltages is substantially uniformly spaced when each respective threshold voltage falls within plus/minus one-quarter “LSB” (i.e., the smallest threshold shift) of the respective desired uniformly spaced value. For example, for the above numerical example, the LSB is equal to the ΔV₁=125 mV, and one-quarter of this value is approximately 31 mV. A value of ΔV₂ within the range of 219 mV to 281 mV would be consistent with this group of substantially uniformly spaced threshold voltages.

To further reduce costs, the memory array may be implemented using no more than two layers of interconnect metallization, and even more preferably all but one layer of metallization may be eliminated. While such a memory array may be time consuming to sense and may be incompatible with high performance operation, such an array may be extremely dense and low-cost. In addition, in certain embodiments it is contemplated that one or more redundancy techniques may be employed, preferably by using error-checking and correction (ECC) techniques for a mask-programmed ROM.

As used herein, “ROM” is synonymous with “mask ROM” or “mask-programmable ROM”, i.e. semiconductor memory whose contents are programmed in the factory, and whose contents may be read but not subsequently altered. The ROM factory is generally a semiconductor manufacturing line, and the programming is usually accomplished via photolithographic steps or “masks” and may therefore be termed mask-programmable. As used herein, any similar spatially-selective operations carried out during semiconductor manufacture, even if a literal mask is not created (e.g., direct ion-beam writing) may be termed “mask-programmable.”

As used herein, word lines and bit lines represent orthogonal array terminal lines, and follow the common assumption in the art that word lines are driven and bit lines are sensed. Thus, bit lines of an array may also be referred to as sense lines of the array. No particular implication should be drawn as to word organization by use of such terms.

Although the invention has been described in the context of a programming each memory cell using selective ion implantation, other techniques may be employed. For example, each memory cell may be configured, during semiconductor manufacture, from more than two possible combinations of memory cell transistor threshold voltage, memory cell transistor width, memory cell transistor length, and memory cell transistor gate oxide thickness, to program within each memory cell more than one bit of information.

Based upon the teachings of this disclosure, it is expected that one of ordinary skill in the art will be readily able to practice the present invention. The descriptions of the various embodiments provided herein are believed to provide ample insight and details of the present invention to enable one of ordinary skill to practice the invention. Nonetheless, in the interest of clarity, not all of the routine features of the implementations described herein are shown and described. It should, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

For example, decisions as to the number of memory cells within each squad, whether to use squad selection devices and their particular configuration, the particular configuration chosen for word line and bit line decoder circuits and bit line sensing circuits, as well as the word organization, are all believed to be typical of the engineering decisions faced by one skilled in the art in practicing this invention in the context of developing a commercially-viable product. Nonetheless, even though a mere routine exercise of engineering effort is believed to be required to practice this invention, such engineering efforts may result in additional inventive efforts, as frequently occurs in the development of demanding, competitive products.

While circuits and physical structures are generally presumed, it is well recognized that in modern semiconductor design and fabrication, physical structures and circuits may be embodied in computer readable descriptive form suitable for use in subsequent design, test or fabrication stages as well as in resultant fabricated semiconductor integrated circuits. Accordingly, claims directed to traditional circuits or structures may, consistent with particular language thereof, read upon computer readable encodings and representations of same, whether embodied in media or combined with suitable reader facilities to allow fabrication, test, or design refinement of the corresponding circuits and/or structures. The invention is contemplated to include circuits, related methods, and computer-readable medium encodings of such circuits and methods, all as described herein, and as defined in the appended claims. As used herein, a computer-readable medium includes at least disk, tape, or other magnetic, optical, semiconductor (e.g., flash memory cards, ROM), or electronic medium and a network, wireline, wireless or other communications medium. An encoding of a circuit may include circuit schematic information, physical layout information, behavioral simulation information, and/or may include any other encoding from which the circuit may be represented or communicated.

The foregoing details description has described only a few of the many possible implementations of the present invention. For this reason, this detailed description is intended by way of illustration, and not by way of limitation. Variations and modifications of the embodiments disclosed herein may be made based on the description set forth herein, without departing from the scope and spirit of the invention. It is only the following claims, including all equivalents, which are intended to define the scope of this invention. Accordingly, other variations, modifications, additions, and improvements may fall within the scope of the invention as defined in the claims that follow.

What is claimed is:

1. An integrated circuit comprising an array of serially-connected, multi-level, mask-programmable read-only memory cells.

2. The invention as recited in claim 1 wherein each memory cell is programmable by selective ion implantation of at least two ion implantation steps to store therewithin more than one bit of information.

3. The invention as recited in claim 1 wherein the memory cell array comprises a plurality of squads, each of said squads comprising a plurality of serially-connected memory cells, each coupled at one end thereof to an associated bit line of the memory array.

4. The invention as recited in claim 1 wherein each memory cell is programmable by configuring, during semiconductor manufacture, from more than two possible combinations of memory cell transistor threshold voltage, memory cell transistor width, memory cell transistor length, and memory cell transistor gate oxide thickness, to store within each of said memory cells more than one bit of information.

5. An integrated circuit including a memory array comprising:
a plurality of memory cell squads, each squad comprising a corresponding plurality of serially-connected memory cells, each squad coupled at one end thereof to an associated bit line of the memory array;
each of said memory cells comprising a read-only memory cell which is mask-programmable to store more than one bit of information therein.

6. The invention as recited in claim 5 wherein each memory cell is mask programmable by selective ion implantation of two or more ion implantation steps to store therewithin more than one bit of information.

7. The invention as recited in claim 5 wherein each respective squad further comprises:
a respective selection device coupled in series with the plurality of serially-connected memory cells of the respective squad.

8. An integrated circuit memory array comprising:
a plurality of memory cell squads, each squad comprising a corresponding plurality of serially-connected single transistor memory cells, each squad coupled at one end thereof to an associated bit line of the memory array;
each of said memory cells comprising a read-only memory cell which is programmed during semiconductor manufacture by selectively ion implanting a combination of N different ion implantations to store more than one bit of information therein.

9. The invention as recited in claim 8 wherein each respective squad further comprises:
a respective selection device coupled between the plurality of serially-connected memory cells of the respective squad and the associated bit line.

10. The invention as recited in claim 8 wherein the plurality of serially-connected memory cells within each squad comprises an integral power of two of such memory cells.

11. The invention as recited in claim 8 wherein the memory array is implemented using at most two layers of interconnect metallization.

12. The invention as recited in claim 8 wherein:
the N different ion implantations are selected such that each of the 2^{N} combinations thereof result in a substantially different threshold voltage of the memory cell transistor.

13. The invention as recited in claim 12 wherein:
the different resultant transistor threshold voltages are substantially uniformly spaced.

14. The invention as recited in claim 12 wherein:
each respective one of the N possible ion implantations results in a respective threshold adjustment to a memory cell transistor which is substantially binary weighted, thereby resulting in 2^{N} substantially uniformly spaced transistor threshold voltages.

15. The invention as recited in claim 12 wherein:
for each ion implantation from 1 to N, the associated threshold adjustment to a memory cell transistor ΔV_{T}(i) for a given one of the N ion implantations is approximately twice that of ΔV_{T}(i−1), for i=2,N; and
the ion implantations are not necessarily performed in order from 1 to N.

16. A method of fabricating an integrated circuit memory array comprising the steps of:
forming a plurality of memory cell squads, each squad comprising a corresponding plurality of serially-connected single transistor memory cells, each squad coupled at one end thereof to an associated bit line of the memory array;
using at least two different masks, selectively ion implanting a combination of at least two possible ion implantations into each memory cell to encode more than one bit of information per memory cell, and thereby resulting in a read-only memory cell.

17. The invention as recited in claim 16 wherein each respective squad further comprises:
a respective selection device coupled between the plurality of serially-connected memory cells of the respective squad and the associated bit line.

18. The invention as recited in claim 16 wherein the plurality of serially-connected memory cells within each squad comprises an integral power of two such serially-connected memory cells.

19. The invention as recited in claim 16 wherein:
N different ion implantations are utilized and selected such that each of the 2^{N} combinations thereof result in a substantially different threshold voltage of the memory cell transistor.

20. The invention as recited in claim 19 wherein:
the different resultant transistor threshold voltages are substantially uniformly spaced.

21. The invention as recited in claim 19 wherein:
each respective one of the N possible ion implantations results in a respective threshold adjustment to a memory cell transistor which is substantially binary weighted, thereby resulting in 2^{N} substantially uniformly spaced transistor threshold voltages.

22. The invention as recited in claim 19 wherein:
for each ion implantation from 1 to N, the associated threshold adjustment to a memory cell transistor ΔV_{T}(i) for a given one of the N ion implantations is approximately twice that of ΔV_{T}(i−1), for i=2,N.

23. The invention as recited in claim 22 wherein:
the ion implantations are not necessarily performed in order from 1 to N.

24. A computer readable medium encoding an integrated circuit including a memory array, said encoded memory array as defined in claim 1.

25. A computer readable medium encoding an integrated circuit including a memory array, said encoded memory array comprising:
a plurality of memory cell squads, each squad comprising a corresponding plurality of serially-connected memory cells, each squad coupled at one end thereof to an associated bit line of the memory array;
each of said memory cells comprising a read-only memory cell which is mask-programmable to store more than one bit of information therein.

26. The invention as recited in claim 25 wherein each respective squad further comprises:
a respective selection device coupled in series with the plurality of serially-connected memory cells of the respective squad.

27. The invention as recited in claim 26 wherein said encoded memory array further includes at least two ion implantation mask layers for programming each memory cell by selective ion implantation of two or more ion implantation steps.
